(19) United States
(12) Patent Application Publication
(10) Pub. No.: US 2011/0309358 A1
(43) Pub. Date: Dec. 22, 2011

(54) SEMICONDUCTOR CHIP WITH FINE PITCH LEADS FOR NORMAL TESTING OF SAME

(75) Inventors: Jong Hoon KIM, Suwon-si (KR); Min Suk SUH, Seoul (KR); Kwon Whan HAN, Seoul (KR); Seung Taek YANG, Seoul (KR)

(73) Assignee: HYNIX SEMICONDUCTOR INC., Icheon-si (KR)

(21) Appl. No.: 12/979,317

(22) Filed: Dec. 27, 2010

(30) Foreign Application Priority Data
Jun. 17, 2010 (KR) 10-2010-0057512

(51) Int. Cl. H01L 23/58

(52) U.S. Cl. 257/48; 257/E23.002

(57) ABSTRACT

A semiconductor chip includes a semiconductor substrate having a top surface and a bottom surface. A circuit layer having bonding pads may be formed over the top surface of the semiconductor substrate. Through electrodes may be formed to pass from a bottom surface to a top surface of the semiconductor substrate, and the through electrodes may comprise through parts connected with the bonding pads and projecting parts formed over the bottom surface of the semiconductor substrate and electrically connected with the through parts. Test pad parts may be disposed over the bottom surface of the semiconductor substrate and is connected with the through electrodes to test normal operation of the circuit layer and electrical connections of the through electrodes and the circuit layer.

### CROSS-REFERENCE TO RELATED APPLICATIONS

The present application claims priority to Korean patent application number 10-2010-0057512 filed on Jun. 17, 2010, which is incorporated herein by reference in its entirety.

### BACKGROUND OF THE INVENTION

The present invention relates to a semiconductor chip that can realize fine pitch for its leads and can test the normal operation of a circuit layer and the electrical connections of through electrodes and the circuit layer.

Semiconductor devices are increasingly capable of processing greater amounts of data. These semiconductor devices comprise semiconductor chips within semiconductor packages. One or more semiconductor chips are processed on, for example, a silicon wafer, a sorting process for electrically inspecting the semiconductor chips (chips are also referred to as “dies”), and a packaging process for packaging good quality semiconductor chips.

In semiconductor packages, it is the norm that electrical connections are formed using metal wires. Recently, in order to overcome the problems caused in the semiconductor packages using the metal wires, suppress the electrical characteristics of the semiconductor packages from being degraded, and enable the miniaturization of the semiconductor packages, research has actively been conducted for semiconductor packages using through electrodes.

In the semiconductor packages using the through electrodes, since electrical connections are formed by the through electrodes, the electrical degradation of the semiconductor packages is substantially prevented, the operation speeds of the semiconductor chips are improved, and it is possible to achieve the miniaturization of the semiconductor packages.

The through electrodes are formed to be connected with bonding pads which are used as the input and/or output terminals of a semiconductor chip. The through electrodes are used as input and/or output terminals of the semiconductor chip along with the is bonding pads.

In general, a semiconductor chip using through electrodes has a markedly increased number of input and/or output terminals when compared to a semiconductor chip not using through electrodes. In the semiconductor chip using through electrodes, in order to allow a probe test to be performed, the bonding pads and the through electrodes which are used as the input and/or output terminals are formed to have sizes greater than a predetermined size. In this case, since the overall size of the semiconductor chip increases due to the formation of the bonding pads and the through electrodes, the number of semiconductor chips manufactured per a wafer cannot but decrease.

In order to solve this problem, the sizes of the bonding pads and the through electrodes are decreased. However, in this case, the reliability of the test is likely to deteriorate due to limitations in processing by probe test equipment, and in a worse case, it may be impossible to conduct a probe test process.

### BRIEF SUMMARY OF THE INVENTION

Various embodiments of the invention may describe layer

A as being “over” or “on” layer B. These terms may mean that layer A is directly on top of layer B, or that there may be at least one other layer between layer A and layer B. Similarly, when layer B is described as being “under” or “below” layer A, layer B may be directly under layer A, or there may be one or more layers between layer A and layer B.

Additionally, when an item Q is described as being “on” a surface Y, the surface Y may be either a top surface or a bottom surface. For example, layer A may be directly over layer B, where a bottom surface A2 of layer A may directly contact a top surface B1 of layer B. An item Q, which may be, for example, a metal pad, may be said to be “on” the top surface A2 of layer A, or “on” the bottom surface B2 of layer B.

An embodiment of the present invention is directed to a semiconductor chip that can realize a fine pitch and can test the normal operation of a circuit layer and the electrical connections of through electrodes and the circuit layer.

In one embodiment of the present invention, a semiconductor chip may include a semiconductor substrate having a top surface and a bottom surface. A circuit layer having bonding pads may be formed over the top surface of the semiconductor substrate. Through electrodes may be formed to pass from a top surface to a bottom surface of the semiconductor substrate. The through electrodes may comprise though parts connected with the bonding pads and projecting parts formed over the bottom surface of the semiconductor substrate. The projecting parts may be electrically connected with the through parts. The semiconductor chip may also comprise test pad parts disposed over the bottom surface of the semiconductor substrate and connected with the through electrodes. The test pad parts may be used to test normal operation of the circuit layer and electrical connections of the through electrodes and the circuit layer.

The test pad parts may comprise test pads formed over the bottom surface of the semiconductor substrate at positions near the through electrodes. The test pads may be, for example, adjacent to the through electrodes. The test pad parts may also comprise test redistribution lines that may connect the through electrodes and the test pads with each other.

The test redistribution lines may be electrically connected with the projecting parts of the through electrodes, and the projecting parts may be formed over the through parts of the through electrodes.

The projecting part of each through electrode may have a first size when viewed from the top, and each test pad may have a second size greater than the first size.

Each test pad may have the shape of any one of a circle, oval, another curved shape, or a polygon when viewed from the top.

The semiconductor chip may further include a lower insulation pattern having first openings that expose the projecting parts of the through electrodes and the test pads of the test pad parts, and covering a portion of the bottom surface of the semiconductor substrate.

The lower insulation pattern may have second openings that may expose portions of test redistribution lines of the test pad parts.

The projecting parts of the through electrodes may be formed over the bottom surface of the semiconductor substrate, and the through electrodes may further have redistribution lines that are formed over the bottom surface of the semiconductor substrate and electrically connect the through parts and the projecting parts with each other.

The test pad parts may include test pads formed over the bottom surface of the semiconductor substrate near the through electrodes. The test pads may be, for example, adjacent to the through electrodes. The test pad parts may also include test redistribution lines connecting the redistribution lines of the through electrodes and the test pads with each other.

The projecting part of each through electrode may have a first size when viewed from the top, and each test pad may have a second size greater than the first size.

Each test pad may have the shape of any one of a circle, oval, another curved shape, or a polygon when viewed from the top.

The semiconductor chip may further include a lower insulation pattern having first openings that may expose the projecting parts of the through electrodes and the test pads of the test pad parts, and cover portions of the bottom surface of the semiconductor substrate.

The lower insulation pattern may have second openings that expose portions of test redistribution lines of the test pad parts.

The semiconductor chip may further includeupper connection members formed over the bonding pads and lower connection members formed over the projecting parts of the through electrodes.

Each of the upper and lower connection members may include a conductive member that includes any one of a solder, a metal, an ACF (anisotropic conductive film) and an ACP (anisotropic conductive paste).

The semiconductor chip may further include ground pads formed over the top surface of the semiconductor substrate and ground through electrodes formed to pass from the bottom surface to the top surface of the semiconductor substrate, where the ground through electrodes may be electrically connected with the ground pads.

The semiconductor chip may further include additional elements formed over the bottom surface of the semiconductor substrate and electrically connected with the ground through electrodes and the through electrodes.

Each of the additional elements may be a passive element or an active element.

Each of the additional elements may include a first metal line formed over the bottom surface of the semiconductor substrate connected with the ground through electrode. Each additional element may also include a second metal line formed to be placed over the first metal line in such a way as to partially overlap the first metal line and be connected with the through electrode. An insulation member may also be interposed between the first and second metal lines.

Each of the additional elements may be, for example, a resistor or a capacitor.

### BRIEF DESCRIPTION OF THE DRAWINGS

FIG. 1 is a plan view illustrating a semiconductor chip in accordance with an embodiment of the present invention.

FIG. 2 is a cross-sectional view taken along the line II-II′ of FIG. 1.

FIG. 3 is a cross-sectional view illustrating a semiconductor chip in accordance with another embodiment of the present invention.

FIG. 4 is a plan view illustrating a semiconductor chip in accordance with another embodiment of the present invention.

FIG. 5 is a cross-sectional view taken along the line V-V′ of FIG. 4.

FIG. 6 is a cross-sectional view used to explain a method for testing electrical connections of semiconductor chips according to the present invention.

FIG. 7 is a plan view illustrating a semiconductor chip in accordance with another embodiment of the present invention.

FIG. 8 is a cross-sectional view taken along the line VIII-VIII′ of FIG. 7.

FIG. 9 is a cross-sectional view illustrating a stack package in accordance with another embodiment of the present invention.

### DESCRIPTION OF SPECIFIC EMBODIMENTS

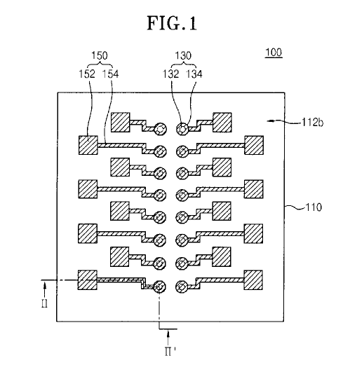

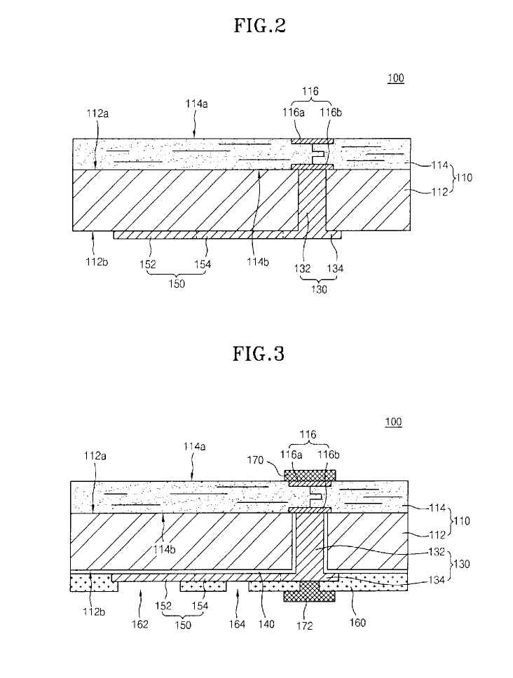

Various embodiments of the present invention will be described in detail with reference to the accompanying drawings. It is to be understood that the drawings are not necessarily to scale and in some instances proportions may have been exaggerated in order to more clearly depict certain features of the invention. FIG. 1 is a plan view illustrating a semiconductor chip in accordance with an embodiment of the present invention, and FIG. 2 is a cross-sectional view taken along the line II-II′ of FIG. 1.

Referring to FIGS. 1 and 2, a semiconductor chip 100 in accordance with an embodiment of the present invention includes a semiconductor chip body 110, through electrodes 130, and test pad parts 150.

The semiconductor chip body 110 has a semiconductor substrate 112 (FIG. 2) and a circuit layer 114 (FIG. 2). The semiconductor substrate 112 has a top surface 112a and a bottom surface 112b. The circuit layer 114 has a lower surface 114b that contacts the top surface 112a of the semiconductor substrate 112 and an upper surface 114a.

The semiconductor substrate 112 may comprise, for example, purified silicon. The circuit layer 114 may comprise a data storage unit (not shown), a data processing unit (not shown), and bonding pads 116. The data storage unit stores data, and the data processing unit processes the data stored in the data storage unit. The bonding pads 116 are used as terminals for inputting and/or outputting signals, and are connected with the data storage unit and/or the data processing unit.

The bonding pads 116 can include first bonding pads 116a formed on the upper surface 114a and second bonding pads 116b formed on the lower surface 114b in such a way as to be electrically connected with the first bonding pads 116a.

The through electrodes 130 are formed to pass from the bottom surface 112b to the top surface 112a of the semiconductor substrate 112. The through electrodes 130 have through parts 132 that are connected with the bonding pads 116 and projecting parts 134 that are formed on the bottom surface 112b of the semiconductor substrate 112 and are electrically connected with the through parts 132. The projecting parts 134 can be formed at positions corresponding to the through parts 132.

The through electrodes 130 may be formed, for example, along the center portion of the semiconductor chip body 110. In this case, the through electrodes 130 may be arranged in at least one row on the center portion of the semiconductor chip body 110. FIG. 1 shows an example in which the through electrodes 130 are arranged in two rows.

The test pad parts 150 are formed on the bottom surface 112b of the semiconductor substrate 112 and are electrically connected with the through electrodes 130. The test pad parts 150 are formed to test the normal operation of the circuit layer 114 and the electrical connections of the through electrodes 130 and the circuit layer 114.

The test pad parts 150 have test pads 152 that are formed at positions near the through electrodes 130 on the other surface 112b of the semiconductor substrate 112, and test redistribution lines 154 that connect the through electrodes 130 and the test pads 152 with each other.

The projecting part 134 of each through electrode 130 has a first size when viewed from the top, and each test pad 152 has a second size greater than the first size. Each test pad 152 can have a geometric shape such as, for example, a circle, an oval, or another curved shape, triangle, quadrangle, pentagon, or another polygon when viewed from the top. The test pads 152 may be disposed, for example, on the peripheral portions of the semiconductor chip body 110.

The test redistribution lines 154 can be electrically connected with the projecting parts 134 of the through electrodes 130. In the present embodiment, since the test pad parts 150, which are connected with the through electrodes 130, are disposed on the other surface 112b of the semiconductor substrate 112, it is possible to test the normal operation of the circuit layer 114 and the electrical connections of the through electrodes 130 and the circuit layer 114.

In an embodiment of the present invention, since the test pad parts 150, which are connected with the through electrodes 130, are disposed on the other surface 112b of the semiconductor substrate 112, it is possible to test the normal operation of the circuit layer 114 and the electrical connections of the through electrodes 130 and the circuit layer 114.

While not shown in a drawing, for example, in the case where the test pad parts 150 are formed to be connected with the first bonding pads 116a which are disposed on the upper surface 114a of the circuit layer 114, it is only possible to test the normal operation of the circuit layer 114 by the medium of the test pad parts 150 which are connected with the first bonding pads 116a, and it is impossible to test the electrical connections of the circuit layer 114 and the through electrodes 130. Conversely, in the case where the test pad parts 150 are formed on the other surface 112b Is of the semiconductor substrate 112 as in an embodiment, it is possible to test the electrical connections of the circuit layer 114 and the through electrodes 130 as well as the normal operation of the circuit layer 114.

In an embodiment of the present invention, due to the formation of the test pad parts 150 that are connected with the through electrodes 130, the bonding pads 116 and the through electrodes 130, which may be used as the input and/or output terminals, can be designed to have smaller sizes when compared to the conventional art.

In the conventional art, because a probe test may need to be performed, limitations exist in decreasing the pitches between the bonding pads 116 and between the through electrodes 130. In an embodiment, by additionally designing the test pad parts 150 that extend from the through electrodes 130, the normal operation of the circuit layer 114 and the electrical connections of the through electrodes 130 and the circuit layer 114 can be tested regardless of the numbers and the sizes of the bonding pads 116 and the through electrodes 130 used as the input and/or output terminals.

Accordingly, in an embodiment of the invention, the sizes of the bonding pads 116 and the projecting parts 134 of the through electrodes 130 and the pitches between the bonding pads 116 and between the projecting parts 134 of the through electrodes 130 can be decreased, thereby increasing the number of semiconductor chips per wafer.

FIG. 3 is a cross-sectional view illustrating a semiconductor chip in accordance with another embodiment of the present invention. The same reference numerals of the aforementioned embodiment will be used in the present invention to refer to the components that are common to both embodiments, and descriptions thereof will not be repeated.

Referring to FIG. 3, a semiconductor chip 100 in accordance with another embodiment of the present invention includes a semiconductor chip body 110, through electrodes 130, test pad parts 150, an insulation layer 140, and a lower insulation pattern 160. The semiconductor chip 100 may further include upper connection members 170 and lower connection members 172.

Since the semiconductor chip 110, the through electrodes 130 and the test pad parts 150 are substantially the same as those of the aforementioned embodiment, repeated descriptions thereof will be omitted herein.

The insulation layer 140 is formed between inner sidewalls of a semiconductor substrate 112 and through parts 132 of the through electrodes 130 and on the bottom surface 112b of the semiconductor substrate 112. Inner sidewalls are exposed in a substrate due to defining of through holes.

The lower insulation pattern 160 is disposed below the insulation layer 140. The lower insulation pattern 160 has first openings 162 that expose projecting parts 134 of the through electrodes 130 and test pads 152 of the test pad parts 150, and is formed to cover a portion of the bottom surface 112b of the semiconductor substrate 112.

Further, the lower insulation pattern 160 has second openings 164 that expose portions of test redistribution lines 154 of the test pad parts 150. The first and second openings 162 and 164 can be defined through a selective etching process using a photo mask.

The first openings 162 of the lower insulation pattern 160 are defined to bring probes into contact with the test pads 152 when performing a probe test process, and the second openings 164 of the lower insulation pattern 160 are defined to selectively disconnect electrically the test pad parts 150 and the through electrodes 130 by using, for example, a laser cutting unit (not shown) as the occasion demands after the probe test process is conducted.

The upper connection members 170 are formed on the first bonding pads 116a of the circuit layer 114. Each upper connection member 170 can have a size corresponding to that of each first bonding pad 116a.

The lower connection members 172 are formed on the projecting parts 134 of the through electrodes 130. Each lower connection member 172 can have a size corresponding to that of the projecting part 134 of each through electrode 130.

The upper and lower connection members 170 and 172 are formed to be used when stacking at least two semiconductor chips 100, and may be omitted as the occasion demands. Each of the upper and lower connection members 170 and 172 can include any one of, for example, a solder, a metal, an ACF (anisotropic conductive film) and an ACP (anisotropic conductive paste).

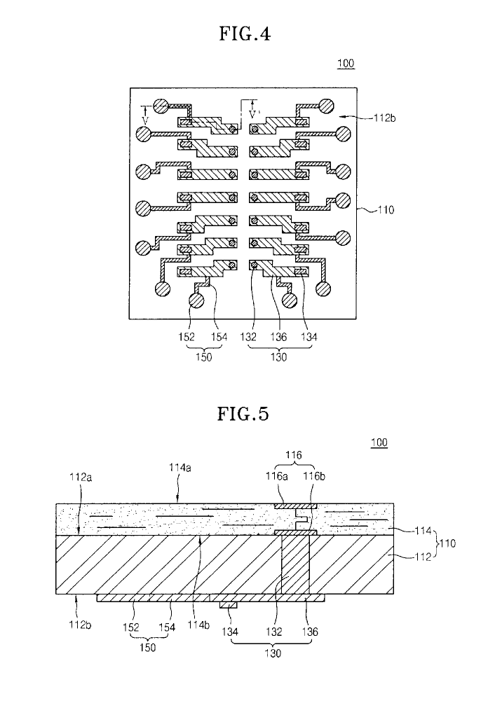

FIG. 4 is a plan view illustrating a semiconductor chip in accordance with another embodiment of the present invention, and FIG. 5 is a cross-sectional view taken along the line V-V′ of FIG. 4.

Referring to FIGS. 4 and 5, a semiconductor chip 100 in accordance with another embodiment of the present invention includes a semiconductor chip body 110, through electrodes 130, and test pad parts 150.

The semiconductor chip body 110 has a semiconductor substrate 112 and a circuit layer 114. The semiconductor substrate 112 has a top surface 112a and a bottom surface 112b. The circuit layer 114 has a lower surface 114b that contacts the top surface 112a of the semiconductor substrate 112 and an upper surface 114a.

The circuit layer 114 may comprise a data storage unit (not shown), a data processing unit (not shown), and bonding pads 116. The bonding pads 116 can include first bonding pads 116a formed on the upper surface 114a of the circuit layer 114 and second bonding pads 116b formed on the lower surface 114b of the circuit layer 114 in such a way as to be electrically connected with the first bonding pads 116a.

The through electrodes 130 can have through parts 132, projecting parts 134, and redistribution lines 136. The projecting parts 134 and the redistribution lines 136 are formed on the bottom surface 112b of the semiconductor substrate 112.Accordingly, the through parts 132 and the projecting parts 134 may be electrically connected with each other by the redistribution lines 136.

The test pad parts 150 include test pads 152 formed on the bottom surface 112b at positions near the through electrodes 130 and test redistribution lines 154 that electrically connect the redistribution lines 136 to the test pads 152.

The projecting part 134 of each through electrode 130 has a first size when viewed from the top, and each test pad 152 has a second size that may be greater than the first size. Each test pad 152 can have a shape such as, for example, a circle, an oval, or another curved shape, a triangle, a quadrangle, a pentagon, or another polygon when viewed from the top.

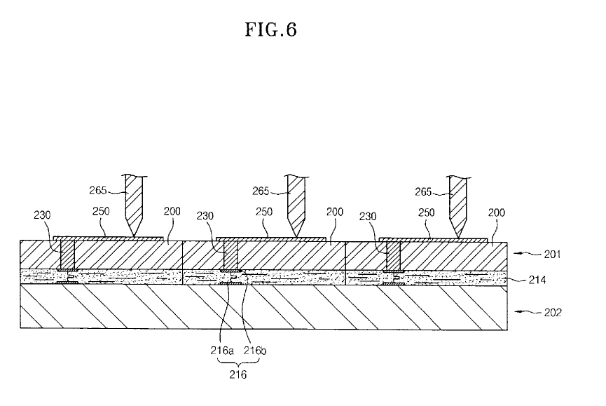

FIG. 6 is a cross-sectional view used to explain a method for testing electrical connections of semiconductor chips according to the present invention.

Referring to FIG. 6, a wafer 201 including a plurality of semiconductor chips 200 is prepared. Each semiconductor chip 200 has a circuit layer 214 that includes bonding pads 216. After attaching the wafer 210 including the semiconductor chips 200 to a carrier wafer 202, through holes (not shown), which expose bonding pads 216 of the respective semiconductor chips 200, are defined.

Through electrodes 230 are formed on the inner sidewalls of the wafer 201, which are exposed due to defining of the through holes, and on the surface of the wafer 201 in such a way as to be connected with the bonding pads 216, and test pad parts 250 are formed in such a way as to extend from the through electrodes 230. After placing a probe card (not shown) having a plurality of probes 265 over the wafer 201, the respective probes 265 are brought into contact with the test pad parts 250, whereby the normal operation of the circuit layer 214 and the electrical connections of the through electrodes 230 and the circuit layer 214 can be tested. After sorting good semiconductor chips or a good wafer through conducting such a probe test process, subsequent processes are conducted.

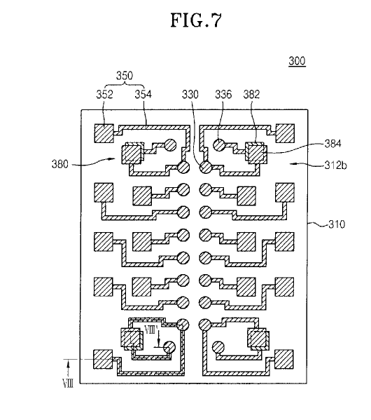

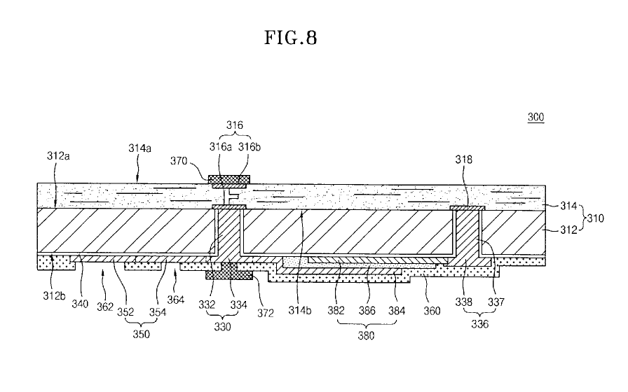

FIG. 7 is a plan view illustrating a semiconductor chip in accordance with another embodiment of the present invention, and FIG. 8 is a cross-sectional view taken along the line VIII-VIII′ of FIG. 7.

Referring to FIGS. 7 and 8, a semiconductor chip 300 in accordance with another embodiment of the present invention includes a semiconductor chip body 310, through electrodes 330, ground through electrodes 336, test pad parts 350, an insulation layer 340, a lower insulation pattern 360, and additional elements 380. The semiconductor chip 300 can further include upper connection members 370 and lower connection members 372.

The semiconductor chip body 310 has a semiconductor substrate 312 and a circuit layer 314. The semiconductor substrate 312 has a top surface 312a and a bottom surface 312b. The circuit layer 314 has a lower surface 314b that contacts the top surface 312a of the semiconductor substrate 312 and an upper surface 314a. The semiconductor substrate 312 may comprise, for example, purified silicon.

The circuit layer 314 may comprise a data storage unit (not shown), a data processing unit (not shown), bonding pads 316, and ground pads 318. The data storage unit stores data, and the data processing unit processes the data stored in the data storage unit. The bonding pads 316 are used as terminals for inputting and/or outputting signals, and are connected with the data storage unit and/or the data processing unit.

The bonding pads 316 can include first bonding pads 316b formed on the upper surface 314a and second bonding pads 316a formed on the lower surface 314b in such a way as to be electrically connected with the first bonding pads 316b. The ground pads 318 are formed on the top surface 312a and may be electrically disconnected from the bonding pads 316. A ground signal is applied to the ground pads 318.

The through electrodes 330 are formed to pass from the bottom surface 312b to the top surface 312a of the semiconductor substrate 312. The through electrodes 330 have through parts 332 connected with the second bonding pads 316a and projecting parts 334 formed on the bottom surface 312b. The projecting parts 334 are electrically connected with the through parts 332.

The through electrodes 330 may be formed along the center portion of the semiconductor chip body 310. In this case, the through electrodes 330 may be arranged in at least one row on the center portion of the semiconductor chip body 310. FIG. 7 shows an example in which the through electrodes 330 are arranged in two rows.

The ground through electrodes 336 are formed to pass from the bottom surface 312b to the top surface 312a of the semiconductor substrate 312. The ground through electrodes 336 have through parts 337 electrically connected with the ground pads 318 and projecting parts 338 formed on the bottom surface 312b. The projecting parts 338 are electrically connected with the through parts 337.

The test pad parts 350 are formed on the bottom surface 312b and are electrically connected with the through electrodes 330. The test pad parts 350 are formed to test the normal operation of the circuit layer 314 and the electrical connections of the through electrodes 330 and the circuit layer 314. The test pad parts 350 have test pads 352 near the through electrodes 330, and test redistribution lines 354 that connect the through electrodes 330 and the test pads 352 with each other.

The projecting part 334 of each through electrode 330 has a first size when viewed from the top, and each test pad 352 has a second size that may be greater than the first size. Each test pad 352 can have a shape such as, for example, a circle, an oval, or another curved shape, a triangle, a quadrangle, a pentagon, or another polygon when viewed from the top.

The test pads 352 may be disposed on the peripheral portions of the semiconductor chip body 310. The test pads 352 may also be disposed on the center portion of the semiconductor chip body 310.

First ends of the test redistribution lines 354 may be connected with the projecting parts 334 of the through electrodes 330, and second ends of the test redistribution lines 354 may be connected with the test pads 352, thereby electrically connecting the through electrodes 330 and the test pads 352

The insulation layer 340 may be formed between the inner sidewalk of the semiconductor substrate 312 and the through parts 332 of the through electrodes 330, between the inner sidewalls of the semiconductor substrate 312 and the through parts 337 of the ground through electrodes 336, and on the bottom surface 312b of the semiconductor substrate 312.

The lower insulation pattern 360 may be disposed below the insulation layer 340. The lower insulation pattern 360 has first openings 362, which expose the projecting parts 334 of the through electrodes 330 and the test pads 352, and may be formed to cover the bottom surface 312b of the semiconductor substrate 312.

Further, the lower insulation pattern 360 has second openings 364 that expose portions of the test redistribution lines 354. The first and second openings 362 and 364 can be defined through a selective etching process using a photo mask.

The upper connection members 370 are formed on the first bonding pads 316b of the circuit layer 314. Each upper connection member 370 may have a size corresponding to that of each first bonding pad 316b.

The lower connection members 372 are formed on the projecting parts 334 of the through electrodes 330. Each lower connection member 372 may have a size corresponding to that of the projecting part 334 of each through electrode 330.

The upper and lower connection members 370 and 372 are formed to be used when stacking at least two semiconductor chips 300, and may be omitted as the occasion demands. Each of the upper and lower connection members 370 and 372 can include any one of, for example, a solder, a metal, an ACF (anisotropic conductive film) and an ACP (anisotropic conductive paste).

Each of the additional elements 380 can include any one of a passive element including a resistor, a capacitor and an inductor and an active element including a transistor. FIGS. 7 and 8 show an example in which capacitors are used as the additional elements 380.

The additional elements 380 are formed on the bottom surface 312b to be selectively connected with the through electrodes 330 and the ground through electrodes 336. The exemplary FIG. 7 shows four additional elements 380. However, various embodiments of the invention are not limited to a specific number of additional elements.

An exemplary embodiment of the additional elements 380 may include a first metal line 382 formed on the bottom surface 312b connected with the ground through electrode 336, a second metal line 384 placed over the first metal line 382 in such a way as to partially overlap with the first metal line 382 and connected with the through electrode 330, and an insulation member 386 between the first and second metal lines 382 and 384.

Accordingly, in a present embodiment of the invention, because the additional elements are disposed in the semiconductor chip body, the reliability of the electrical connections of the circuit layer may be improved, and it may be possible to realize a semiconductor chip suitable for processing data at a high speed.

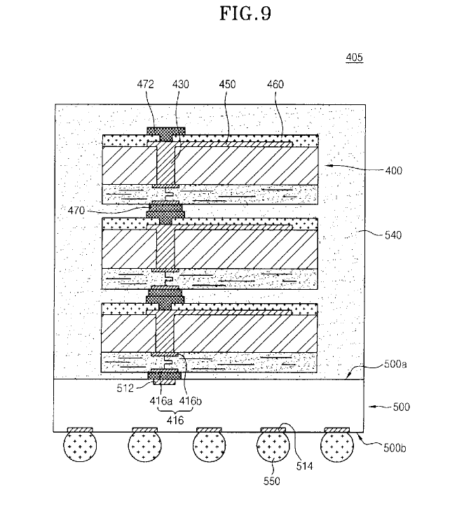

FIG. 9 is a cross-sectional view illustrating a stack package in accordance with another embodiment of the present invention.

Referring to FIG. 9, a stack package 405 in accordance with another embodiment of the present invention includes at least two semiconductor chips 400 that are stacked. The stack package 405 can further include a substrate 500 on which the stacked semiconductor chips 400 are mounted.

Each semiconductor chip 400 is substantially the same as any of the described embodiments of the invention. FIG. 9 shows the semiconductor chip in accordance with another embodiment shown in FIG. 3, and thus, repeated descriptions will be omitted herein.

The stacked semiconductor chips 400 are stacked such that bonding pads 416 of an upwardly positioned semiconductor chip 400 and through electrodes 430 of a downwardly positioned semiconductor chip 400 are electrically connected with one another by the upper and lower connection members 470 and 472 and are physically attached to each other by underfill members (not shown) interposed between the upwardly positioned semiconductor chip 400 and the downwardly positioned semiconductor chip 400.

While not shown in a drawing, the stacked semiconductor chips 400 may also be electrically and physically connected with one another by anisotropic conductive films (not shown) interposed between the upwardly positioned semiconductor chip 400 and the downwardly positioned semiconductor chip 400. In this case, the upper and lower connection members 470 and 472 of the respective semiconductor chips 400 may not be formed.

The substrate 500 has an upper surface 500a and a lower surface 500b. The substrate 500 includes circuit patterns (not shown) that have bond fingers 512 disposed on the upper surface 500a and ball lands 514 disposed on the lower surface 500b.

The bond fingers 512 of the substrate 500 can be connected with the bonding pads 416 of a lowermost semiconductor chip 400 among the stacked semiconductor chips 400 or with the through electrodes 430 of the stacked semiconductor chips 400.

The stack package 405 can further include an encapsulation member 540 and external connection terminals 550.

The encapsulation member 540 is formed to seal the upper surface 500a of the substrate 500 including the stacked semiconductor chips 400. The encapsulation member 540 can include, for example, an EMC (epoxy molding compound).

The external connection terminals 550 are attached to the ball lands 514 which are disposed on the lower surface 500b of the substrate 500. The external connection terminals 550 can include, for example, solder balls.

Although specific embodiments of the present invention have been described for illustrative purposes, those skilled in the art will appreciate that various modifications, additions and is substitutions are possible, without departing from the scope and the spirit of the invention as disclosed in the accompanying claims.

What is claimed is:

1. A semiconductor chip comprising:
a semiconductor substrate having a top surface and a bottom surface;
a circuit layer formed over the top surface of the semiconductor substrate and having bonding pads;
through electrodes formed to pass from a bottom surface to the top surface of the semiconductor substrate, and comprising through parts connected with the bonding pads and projecting parts formed on the bottom surface of the semiconductor substrate; and
test pad parts disposed on the bottom surface of the semiconductor substrate and connected with the through electrodes.

2. The semiconductor chip according to claim 1, wherein is the test pad parts comprise:
test pads formed over the bottom surface of the semiconductor substrate at positions near the through electrodes; and
test redistribution lines connecting the through electrodes and the test pads with each other.

3. The semiconductor chip according to claim 2, wherein the test redistribution lines are electrically connected with the projecting parts of the through electrodes, and the projecting parts are formed over the through parts of the through electrodes.

4. The semiconductor chip according to claim 2, wherein the projecting part of each through electrode has a first size when viewed from the top, and each test pad has a second size greater than the first size.

5. The semiconductor chip according to claim 2, wherein each test pad has the shape of any one selected among a circle, an oval, and polygons when viewed from the top.

6. The semiconductor chip according to claim 2, further comprising:
a lower insulation pattern having first openings that expose the projecting parts of the through electrodes and the test pads of the test pad parts, and covering a portion of the bottom surface of the semiconductor substrate.

7. The semiconductor chip according to claim 6, wherein the lower insulation pattern has second openings that expose portions of test redistribution lines of the test pad parts.

8. The semiconductor chip according to claim 1, wherein the through electrodes comprise redistribution lines that electrically connect the through parts and the projecting parts with each other.

9. The semiconductor chip according to claim 8, wherein the test pad parts comprise:
test pads formed over the bottom surface of the semiconductor substrate at positions near the through electrodes; and
test redistribution lines connecting the redistribution lines of the through electrodes and the test pads with each other.

10. The semiconductor chip according to claim 9, wherein, when viewed from the top, the projecting part of each through electrode has a first size and each test pad has a second size greater than the first size.

11. The semiconductor chip according to claim 9, wherein each test pad has the shape of any one selected among a circle, an oval, and polygons when viewed from the top.

12. The semiconductor chip according to claim 9, further comprising:
a lower insulation pattern having first openings that expose the projecting parts of the through electrodes and the test pads of the test pad parts, and cover portions of the bottom surface of the semiconductor substrate.

13. The semiconductor chip according to claim 12, wherein the lower insulation pattern has second openings that expose portions of test redistribution lines of the test pad parts.

14. The semiconductor chip according to claim 1, further comprising:
upper connection members formed over the bonding pads; and
lower connection members formed over the projecting parts of the through electrodes.

15. The semiconductor chip according to claim 14, wherein each of the upper and lower connection members comprises a conductive member that includes any one of a solder, a metal, an ACF (anisotropic conductive film) and an ACP (anisotropic conductive paste).

16. The semiconductor chip according to claim 1, further comprising:
ground pads formed over the top surface of the semiconductor substrate; and
ground through electrodes formed to pass from the bottom surface to the top surface of the semiconductor substrate, and electrically connected with the ground pads.

17. The semiconductor chip according to claim 16, further comprising:
additional elements formed over the bottom surface of the semiconductor substrate and electrically connected with the ground through electrodes and the through electrodes.

18. The semiconductor chip according to claim 17, wherein each of the additional elements comprises a passive element or an active element.

19. The semiconductor chip according to claim 17, wherein each of the additional elements comprises:
a first metal line formed over the bottom surface of the semiconductor substrate to be connected with the ground through electrode;
a second metal line formed to be placed over the first metal line in such a way as to partially overlap with the first metal line and be connected with the through electrode; and
an insulation member interposed between the first and second metal lines.

20. The semiconductor chip according to claim 19, wherein each of the additional elements comprises a resistor or a capacitor.
